(19) United States
(12) Patent Application Publication
(10) Pub. No.: US 2016/0035677 A1
(43) Pub. Date: Feb. 4, 2016

(54) METHOD FOR FORMING A PACKAGE ARRANGEMENT AND PACKAGE ARRANGEMENT

(71) Applicant: INFINEON TECHNOLOGIES AG, Neubiberg (DE)

(72) Inventors: Ulrich Wachter, Regensburg (DE); Thomas Kilger, Regenstauf (DE)

(21) Appl. No.: 14/450,307

(22) Filed: Aug. 4, 2014

(51) Int. Cl. H01L 23/552; H01L 23/31; H01L 21/683; H01L 21/56; H01L 21/48

(52) U.S. Cl. CPC H01L 23/552; H01L 21/565; H01L 21/4825; H01L 21/6835; H01L 23/3157

(57) ABSTRACT

A method for forming a package arrangement is provided, which may include: arranging at least one chip over a carrier; at least partially encapsulating the at least one chip with encapsulation material, wherein the encapsulation material is formed such that at least a portion of the carrier is uncovered by the encapsulation material; forming an electrically conductive structure over the encapsulation material and on the portion of the carrier uncovered by the encapsulation material; removing the carrier; and then forming a redistribution structure over the chip and the electrically conductive structure, wherein the redistribution structure electrically couples the electrically conductive structure and the chip.

### TECHNICAL FIELD

Various embodiments relate generally to a method for forming a package arrangement and to a package arrangement.

### BACKGROUND

Semiconductor chips, for example in embedded waver level ball grid array packages (eWLB packages), often require a shielding for protection from electromagnetic interference.

A contact, for example an electrically conductive contact, between a front side and a back side of a package may for example be obtained by dedicated dies or chips contacting both, the front side and the back side, inserted between the front side and the back side of the package. Alternatively, through contacts electrically connecting the front side and the back side may be implemented. However, this leads to extra costs and additional processing time incurred through either additional pick-and-place-processes or additional laser drilling processes etc.

### SUMMARY

A method for forming a package arrangement is provided. The method may include: arranging at least one chip over a carrier; at least partially encapsulating the at least one chip with encapsulation material, wherein the encapsulation material is formed such that at least a portion of the carrier is uncovered by the encapsulation material; forming an electrically conductive structure over the encapsulation material and on the portion of the carrier uncovered by the encapsulation material; removing the carrier; and then forming a redistribution structure over the chip and the electrically conductive structure, wherein the redistribution structure electrically couples the electrically conductive structure and the chip.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A to FIG. 1G show a process flow for a method for forming a package arrangement in accordance with various embodiments;

FIG. 2A to FIG. 2C show a process flow for a method for forming a package arrangement in accordance with various embodiments;

FIG. 3 shows a cross section of a package arrangement during a stage of its production in accordance with various embodiments;

FIG. 4 shows a cross section of a package arrangement during a stage of its production in accordance with various embodiments;

FIG. 5 shows a schematic diagram of a method for forming a package arrangement in accordance with various embodiments;

FIG. 6 shows a cross section of a package arrangement in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various embodiments provide a method for forming a package arrangement, for example an eWLB package arrangement, that may provide a cost efficient and reliable shielding, or an integrated metal back side (which may be suitable for serving as an antenna, a back side contact or a heat sink, for example).

According to various embodiments, the method may work without additional pick-and-place processes or laser drilling. Required cavities (or dents) may be formed for example by molding using a special mold tool, or by sawing with a conically shaped sawing blade for structuring an isolating material. Alternatively, suitable isolating materials may be laminated, dispensed or printed onto an eWLB carrier. The cavity may be formed in such a way that it extends to the carrier. Into the cavities and onto the chips or dies covered with isolating material, for example onto back sides of partial recon dies, which may be already placed and molded dies as an eWLB package (this means one reconstitution process happened), a metal layer, for example a copper (Cu) layer, may be formed at carrier level, for example sputter deposited (also termed “sputtered”) or laminated. Thereafter, further molding may be applied for forming mold over the metal layer.

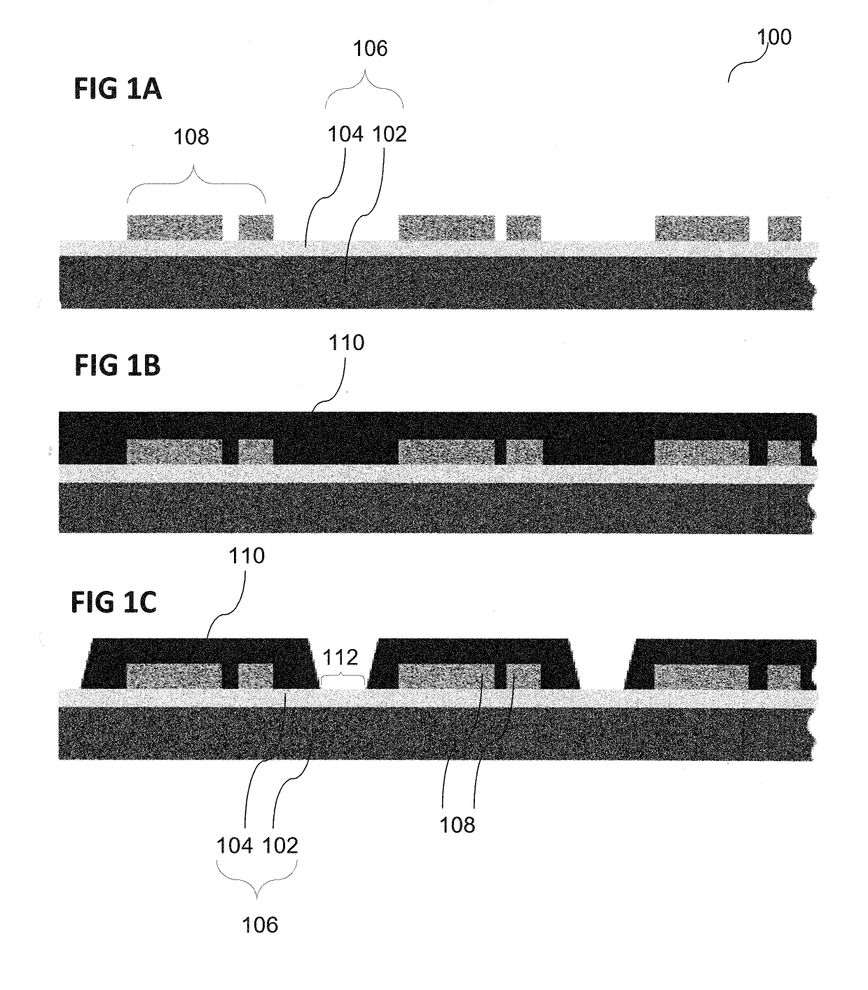

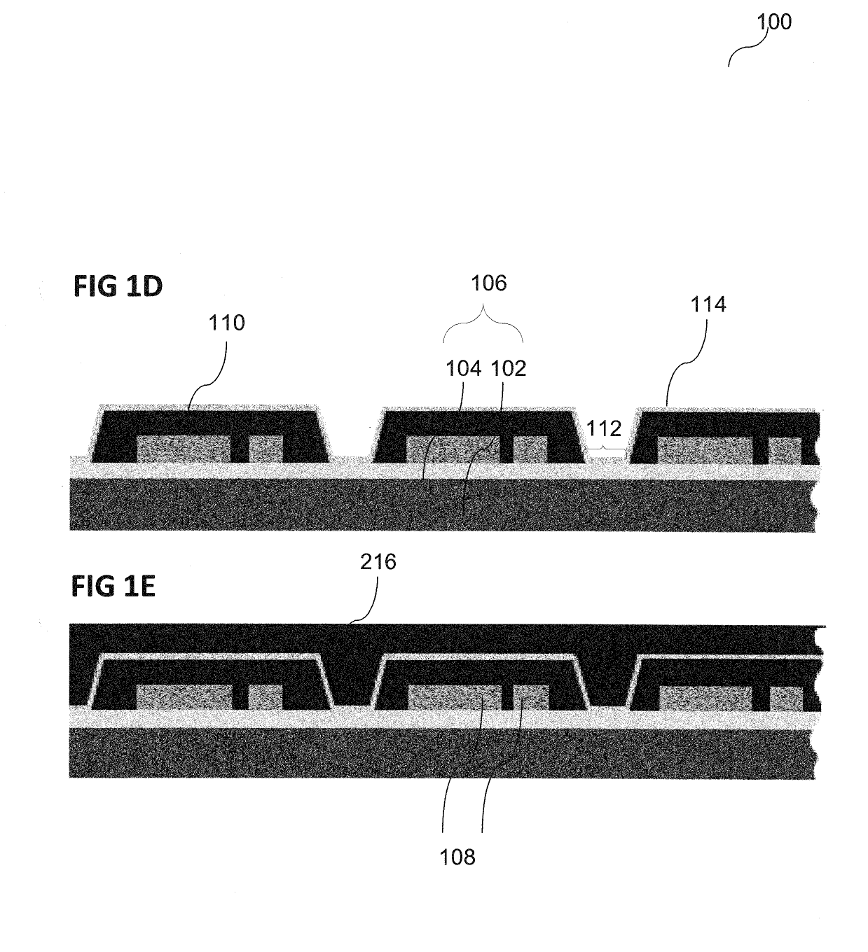

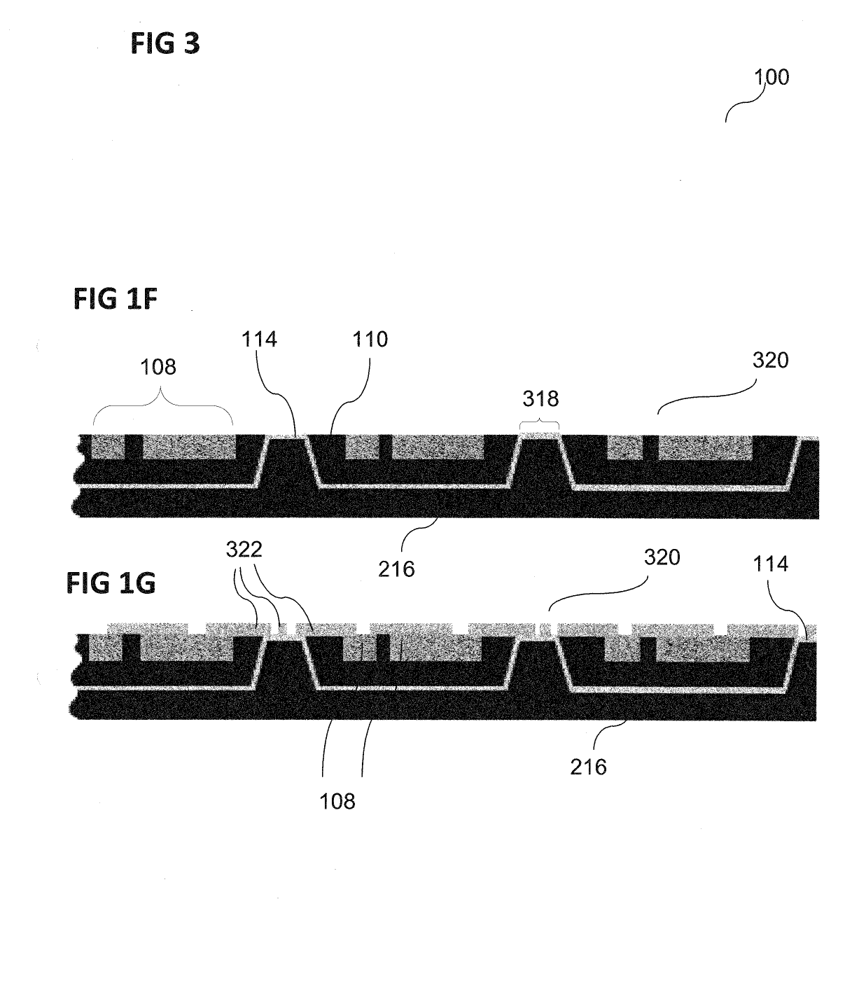

FIG. 1A to FIG. 1G show a process flow for a method for forming a package arrangement 100 in accordance with various embodiments.

As shown in FIG. 1A, the method for forming a package arrangement 100 may include arranging at least one chip 108 over a carrier 106.

The chip 108 may be or include a transistor. For example, the chip 108 may be or include a metal oxide field effect transistor (MOSFET) such as a power MOSFET. The chip 108 may alternatively or additionally be or include a bipolar transistor such as an insulated gate bipolar transistor (IGBT). The chip 108 may include an integrated circuit such as a logic integrated circuit, a memory integrated circuit or a power integrated circuit. The integrated circuit may be an application specific integrated circuit (ASIC) or a field programmable gate array (FPGA). As an alternative, the integrated circuit may be any other programmable logic circuit such as e.g. a programmable processor, e.g. a programmable microprocessor or programmable nanoprocessor. The chip 108 may additionally or alternatively include a capacitor, an inductor, a resistor or any other electrical components.

In various embodiments, the carrier 106 may include a carrier base 102 and a film 104. In various embodiments, the film 104 may be laminated onto the carrier base 102. In various embodiments, the carrier may form a laminated eWLB carrier. In various embodiments, the carrier 106 may not include the film 104, but may include or consist only of the carrier base 102. In various other embodiments, the carrier 106 may include or consist of more than two layers.

In various embodiments, the carrier base 102 may include or consist of a rigid material, for example a semiconductor material, for example silicon, or a dielectric material, for example glass, or a conductive material, for example aluminum. In various other embodiments, the carrier base 102 may include or consist of a flexible material, for example a foil, for example a plastic foil.

In various embodiments, the film 104 may include or consist of a material that is suitable for keeping the chip 108 fixed to the carrier base 102, and/or for facilitating a removal of the carrier 106 from the chip 108 (and from encapsulation material and electrically conductive material yet to be applied) in a future process. In various embodiments, the film may include or consist of some special thermal releasable adhesives. This foil may be a standard foil for eWLB processing with an adhesive thin film on both sides.

As shown in FIG. 1B, the method for forming a package arrangement 100 may include at least partially encapsulating the at least one chip 108 with encapsulation material 110. The encapsulation material 110 may include a dielectric material. The encapsulation material may include at least one material from the following group of materials, the group including or consisting of a molding compound, a dispensable or printable material, filled or unfilled epoxy, pre-impregnated composite fibers, reinforced fibers, a thermoset material, a thermoplastic material, filler particles, laminate, fiber-reinforced laminate, fiber, reinforced polymer laminate, or fiber-reinforced polymer laminate with filler particles.

As shown in FIG. 1 C, the encapsulation material 110 may be formed such that at least a portion 112 of the carrier 106 is uncovered by the encapsulation material 110.

In various embodiments, the encapsulation material 110 may be formed such that the at least one chip 108 is only partially encapsulated. For example, the encapsulation material 110 may be formed only over a side of the chip 108 that is facing away from the carrier 106. In that case, the portion 112 of the carrier 106 uncovered by the encapsulation material 110 may extend from one edge of a first chip 108 to an edge of an adjacent chip 108, wherein the edge of the adjacent chip 108 may be facing towards the first chip 108. In various other embodiments, the encapsulation material 110 may be formed such that the chip 108 is completely encapsulated by the encapsulation material 110 and the carrier 106. In other words, the encapsulation material 110 may be formed over and/or around the chip 108 that is arranged on the carrier 106 in such a way, that no surface of the chip 108 remains exposed to the outside of the chip.

In various embodiments, forming the encapsulation material 110 such that at least a portion of the carrier 106 is uncovered by the encapsulation material 110 may include arranging encapsulation material 110 over the at least one chip 108 and the carrier 106, as shown in FIG. 1B, and then partially removing the encapsulation material 110, for example by sawing the encapsulation material, for example using a conically shaped sawing blade, such that at least a portion 112 of the carrier 106 is uncovered by the encapsulation material 110.

In various embodiments, encapsulating the chip 108 may include using a molding process. Encapsulating the chip 108 may include bringing a mold (not shown) to or over the chip 108, such that at least one mold cavity is formed between the mold and the chip 108, and such that at least a portion of the carrier 106 is not covered by the mold cavity. The encapsulation process may further include heating the encapsulation material, for example a molding compound, until it is liquefied. The process may further include flowing the liquefied encapsulation material 110 into the at least one mold cavity. In addition, the process may include allowing the liquefied encapsulation material 110 (e.g. molding compound) to solidify (e.g. under elevated temperature and pressure), such that the chip 108 is encapsulated by the encapsulation material 110 (e.g. molding compound), while at least a portion 112 of the carrier 106 is uncovered by the encapsulation material 110.

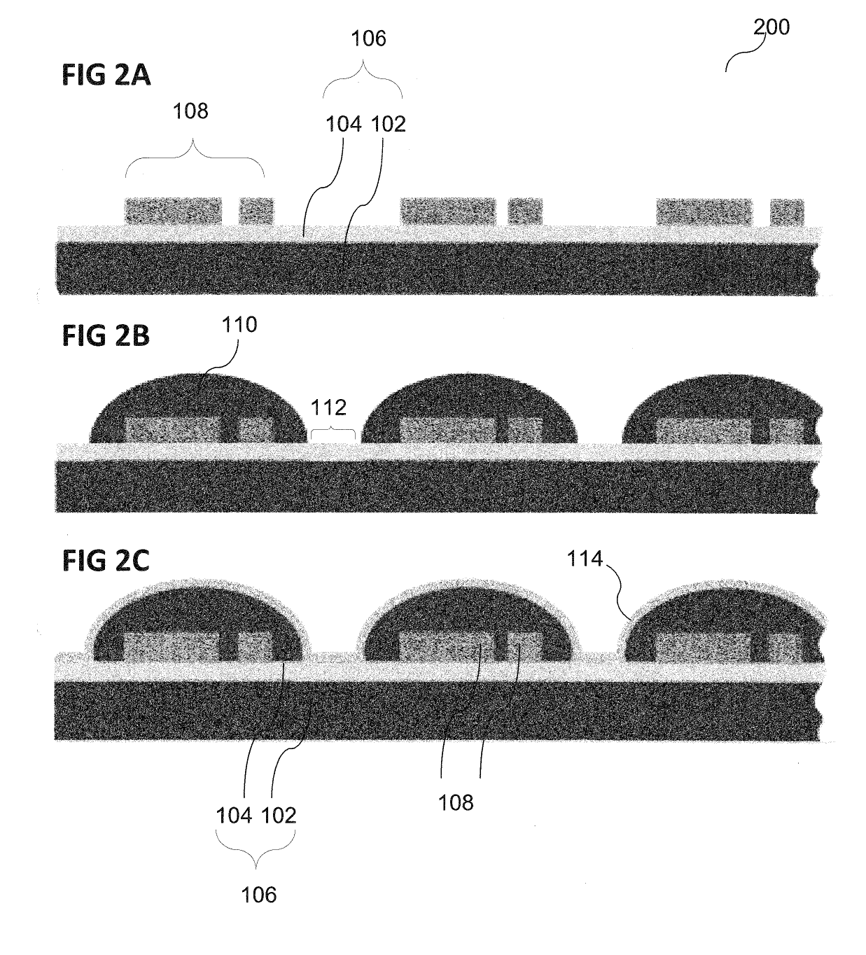

In various embodiments, encapsulating the chip 108 may include laminating the chip 108, for example by arranging an encapsulation material 110 consisting of or including a laminating film on or over the chip 108 and the carrier 106, for example using an adhesive (not shown), such that the at least one chip 108 is encapsulated by the encapsulation material 110 (e.g. the laminate) and the carrier 106, but at least a portion 112 of the carrier 106 may remain uncovered by the encapsulation material 110 (e.g. the laminate). Other ways of forming the encapsulation material 110 will be described in the context of various embodiments shown in FIG. 2B.

In various embodiments, the encapsulation material 110 may have a thickness of 300 μm to 900 μm.

As shown in FIG. 1D, the method for forming a package arrangement 100 may include forming an electrically conductive structure 114 over the encapsulation material 110 and on the portion 112 of the carrier uncovered by the encapsulation material 110. The electrically conductive structure 114 may include metal or conductive ink or any electrically conductive material. The electrically conductive structure 114 may have a resistivity of less than 10⁻⁴ Ωm, for example a resistivity in the range from about 10⁻⁸ Ωm to about 10⁻⁴ Ωm.

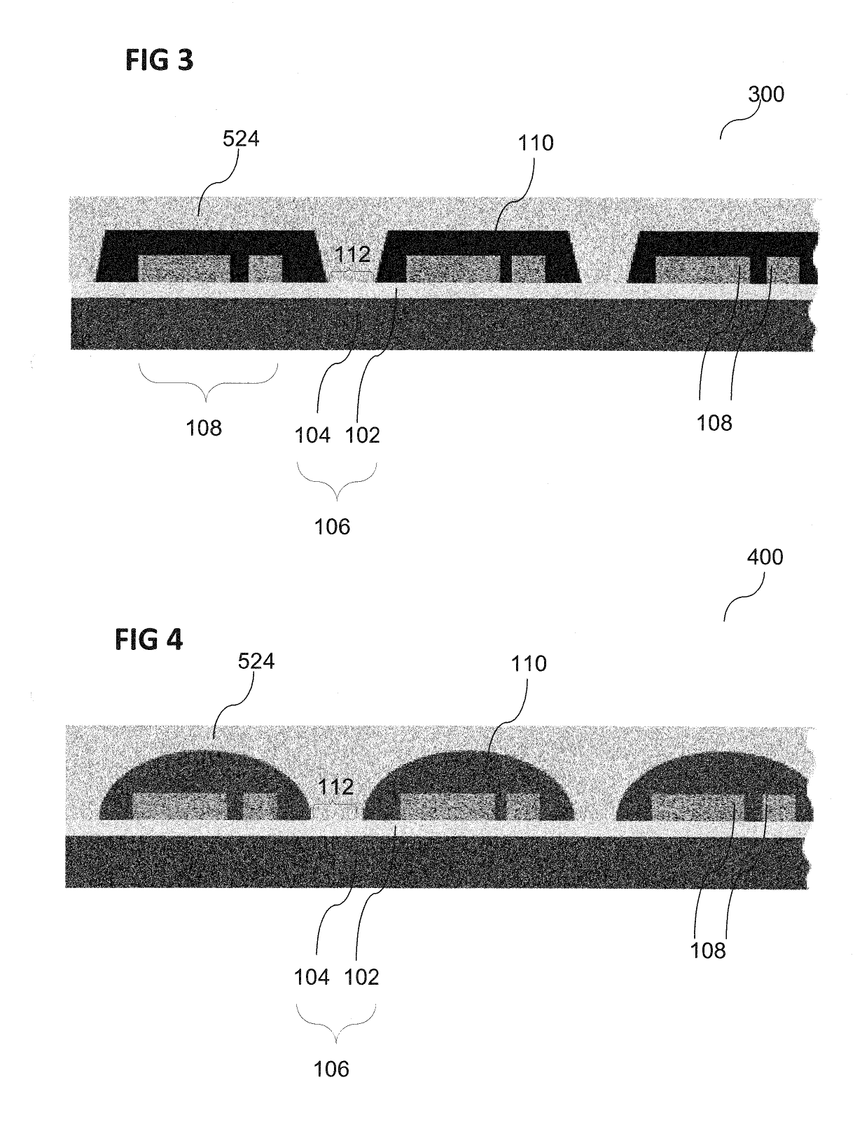

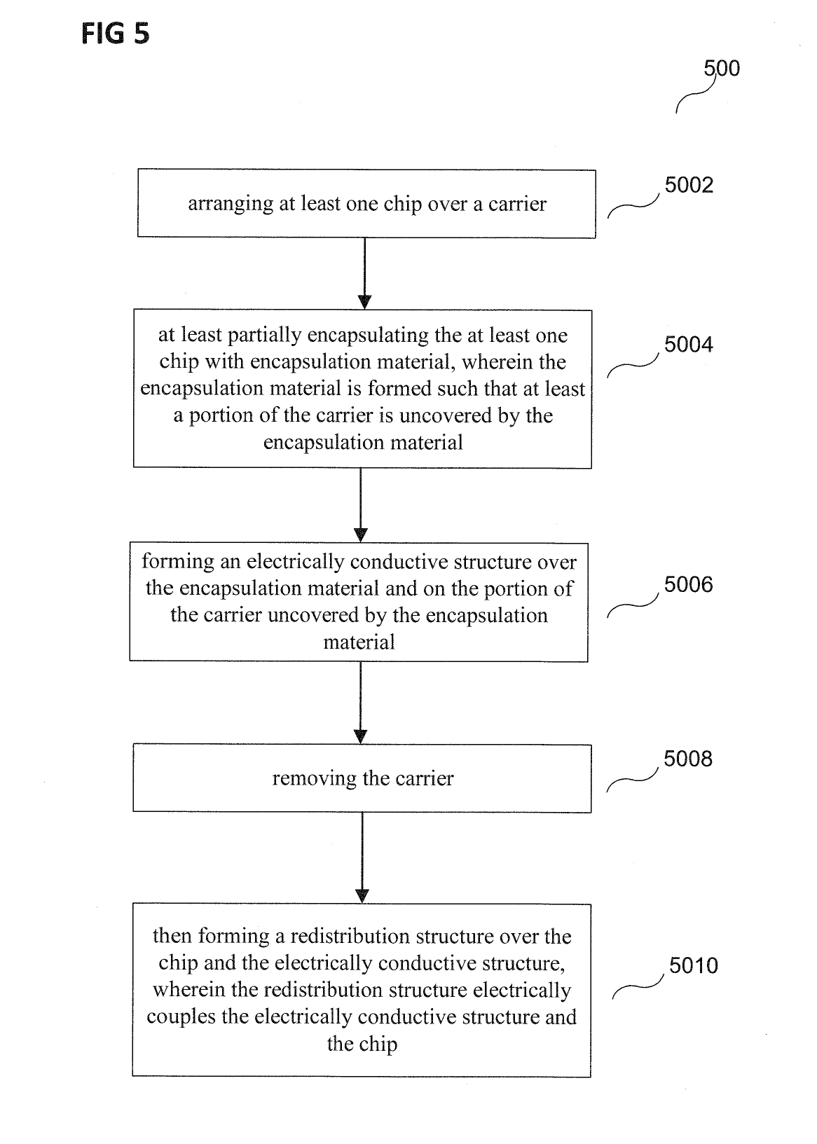

In various embodiments, the electrically conductive structure 114 may be formed by sputtering, i.e. sputter depositing, metal atoms onto the encapsulation material 110 and on the portion 112 of the carrier 106 uncovered by the encapsulation material 110. The metal atoms may include or be copper (Cu) atoms. In various other embodiments, other techniques may be used for forming the electrically conductive structure 114, for example other thin film deposition techniques, galvanic deposition, electroplating, galvanic electroplating, evaporation, chemical deposition such as other physical vapor deposition techniques, or laminating of a pre-formed electrically conductive structure 114 over the encapsulation material 110 and on the portion 112 of the carrier uncovered by the encapsulation material. Further materials and techniques that may be used for forming the electrically conductive structure will be described in context with FIGS. 3 and 4.

In various embodiments, the electrically conductive structure 114 may be configured as a radio frequency shielding structure. In various embodiments, the electrically conductive structure 114 may be configured as a heat sink. The electrically conductive structure 114 may be configured as an antenna. Furthermore, the electrically conductive structure 114 may be configured as a back side contact.

The electrically conductive structure 114 may have a thickness in the range from about 100 nm to about 5 μm.

In various embodiments, the electrically conductive structure 114 may cover the encapsulation material 110 over the at least one chip 108 and the portion 112 of the carrier 106 uncovered by the encapsulation material 110 completely. The electrically conductive structure 114 may be discontinuous and may cover only parts of the encapsulation material 110 over the at least one chip 108 and parts of the portion 112 of the carrier 106 uncovered by the encapsulation material 110.

As shown in FIG. 1E, the method for forming a package arrangement 100 may include forming further encapsulation material 216 over the electrically conductive structure 114. The further encapsulation material 216 may be or include the same material as the encapsulation material 110. In various embodiments, the further encapsulation material 216 may be or include a different material. The further encapsulation material 216 may be or include a dielectric material, for example a molding compound applied in a process similar to the process described in context with FIG. 1C. In various embodiments, the further encapsulation material 216 may be or include an electrically conductive material, for example an electrically conductive plastic material, for example one of the materials listed in context with the electrically conductive structure of FIG. 3 or FIG. 4. The further encapsulation material 216 may be or include a semiconductor material. In various embodiments, the further encapsulation material 216 may be or include a flexible material. In other embodiments, the further encapsulation material 216 may be or include a solid material. The further encapsulation material 216 may have a thickness of in the range from about 100 μm to about 500 μm.

As shown in FIG. 1F, the method may include removing the carrier 106. The techniques used for removing the carrier 106 depend on the material of the carrier 106, i.e. of the carrier base 102 and, if applicable, of the film 104, and on how the chip 108, the encapsulation material 110 and the electrically conductive structure 114 are fixed to the carrier 106. In various embodiments, the carrier 106 may be de-bonded from the chip 108, the encapsulation material 110 and the electrically conductive structure 114. In various other embodiments, the carrier 106 may be removed by means of a standard de-bonding process for eWLB wafer processing. This means that a first side of the carrier 106 may be removed by means of a temperature de-bonding process where also a second side of the carrier 106 over which the chip 108 had been arranged may lose its adhesive force and could then be removed.

In various embodiments, after the removal of the carrier, one side of the chip 108, portions of the encapsulation material 110 and portions 318 of the electrically conductive material 114, which had previously been in contact with or covered by the portions of the carrier 112 uncovered by encapsulation material 110, are exposed on the same side 320 of the package arrangement 100. In various embodiments, also portions of the further encapsulation material 216 may be exposed on the same side 320 of the package arrangement 100 as the one side of the chip 108, the portions of the encapsulation material 110 and the portions 318 of the electrically conductive material 114. In various other embodiments, no portions of the encapsulation material 110 may be exposed on the same side 320 of the package arrangement 100 as the one side of the chip 108 and the portions 318 of the electrically conductive material 114. In various embodiments, an edge of the chip 108 connecting the one side of the chip 108 and the side of the chip opposite the one side of the chip may be in contact with the conductive material.

As shown in FIG. 1G, the method may include then forming a redistribution structure 322 over the chip 108 and the electrically conductive structure 114, wherein the redistribution structure 114 electrically couples the electrically conductive structure 114 and the chip 108. The redistribution structure 322 may be formed on the side 320 of the package arrangement 100 after the removal of the carrier 106. In various embodiments, the redistribution structure may electrically couple the electrically conductive structure 114 and the chip 108 by being electrically connected to at least one portion 318 of the electrically conductive structure 114 exposed after the removal of the carrier 106 and the at least one chip 108. The redistribution structure 322 may be discontinuous.

In various embodiments, the redistribution structure 322 may include one or more metallization layers or interconnects. The metallization layers or interconnects may include an electrically conductive material such as e.g. a metal such as e.g. copper or aluminum. The metallization layers or interconnects may be configured for current redistribution. In other words, the metallization layer or interconnects may serve as or be configured as one or more redistribution layers (RDLs). The redistribution structure 322 may further include one or more dielectric or insulating material/layers such as polymer (e.g. polyimide, epoxy, silicone, ormocere etc) or silicon oxide. The metallization layers (or interconnects) may be separated from one another by the dielectric (or insulating) layers. The redistribution structure 322 may include a laminate. The redistribution structure 322 may include a glass fiber core, for example.

In various embodiments, the redistribution structure 322 may have a thickness in a range from about 5 μm to about 1000 μm, e.g. from about 10 μm to about 200 μm.

In various embodiments, the multi-layer structure may include a thin-film multi-layer structure. The redistribution structure 322 may include one or more thin film metallization layers. The redistribution structure 322 may also include one or more thin film dielectric or insulating layers. The thin film metallization layers may be separated from one another by the dielectric (or insulating) layers. Each thin-film layer may have a thickness below about 50 μm, e.g. below about 15 μm e.g. from about 0.5 μm to about 10 μm.

In various embodiments, the redistribution structure 322 may be coupled to a reference potential. The chip 108 may provide the reference potential. The reference potential may be at ground. In various embodiments, the electrically conductive structure 114 may be configured as an electromagnetic shield such as a radio frequency shielding structure. The electrically conductive structure 114 may be electrically coupled to the chip 108 via the redistribution structure 322. The electrically conductive structure 114 may be also coupled to the reference potential.

In various embodiments, the package arrangement 100 may undergo further processing for eWLB wafer production (not shown), e.g. processing suitable for thin film production.

As shown in FIG. 2A, a method for forming a package arrangement 200 may include arranging at least one chip 108 over a carrier 106. The at least one chip 108 and the carrier 106 may be or include the same materials or elements as described in connection with FIG. 1A.

As shown in FIG. 2B, the method may include at least partially encapsulating the at least one chip 108 with encapsulation material 110 such that at least a portion 112 of the carrier 106 remains uncovered by the encapsulation material 110. The encapsulation material 110 may include or consist of a dielectric material, for example a dielectric dispensable or printable dielectric material, or a dielectric laminate. In various embodiments, forming the encapsulation material 110 such that at least a portion of the carrier 106 remains uncovered by the encapsulation material 110 may include arranging encapsulation material 110 only over the at least one chip 108 and a portion of the carrier 106, such that no encapsulation material 110 is arranged (and later removed) on the portion 112 of the carrier 106. In various embodiments, the encapsulating of the at least one chip 108 with encapsulation material 110 may be achieved by dispensing, printing or laminating of the encapsulation material 110. The encapsulation material 110 may include or consist of any suitable dielectric material or combination of materials that may be applied by dispensing, printing or laminating, respectively. The thickness and structure of the encapsulation material 110 may be the same as described in connection with FIG. 1B and FIG. 1C.

The process as shown in FIG. 2C of forming an electrically conductive structure 114 over the encapsulation material 110 and on the portion 112 of the carrier 106 uncovered by the encapsulation material 110 in a package arrangement 200 may, in various embodiments, be the same as the process described in connection with FIG. 1D. Also material, structure, etc. of the electrically conductive structure 114 may be the same as described in connection with FIG. 1D. Also the subsequent processes may be the same as those as described in connection with FIG. 1E to FIG. 1G.

FIG. 3 shows forming an electrically conductive structure 524 over encapsulation material 110 and on a portion 112 of a carrier 106 uncovered by the encapsulation material 110 in a package arrangement 300. The carrier 106, the chip 108 and the encapsulation material 110 may be identical to various embodiments described in connection with FIG. 1A to FIG. 1C. In various embodiments, the electrically conductive structure 524, however, may include or consist of a conductive molding compound, for example an electrically conductive molding compound. The electrically conductive molding compound may in various embodiments include or consist of a plastic material doped with electrically conductive material, for example doped with carbon black, carbon fibers and/or with metal particles. The electrically conductive structure 524 may have a resistivity of less than 10⁻⁴ Ωm, for example a resistivity in the range from about 10⁻⁷ Ωm to about 10⁻⁴ Ωm.

In various embodiments, the electrically conductive structure 524 of the package arrangement 300, for example the electrically conductive molding compound, may be formed analogously to the molding described in connection with forming the encapsulation material 110 in FIG. 1C.

FIG. 4 shows forming an electrically conductive structure 524 over encapsulation material 110 and on a portion 112 of a carrier 106 uncovered by the encapsulation material 110 in a package arrangement 400. The carrier 106, the chip 108 and the encapsulation material 110 may be identical to various embodiments described in connection with FIG. 2A to FIG. 2C. In various embodiments, the electrically conductive structure 524, however, may include or consist of a conductive molding compound, for example an electrically conductive molding compound. The electrically conductive molding compound may in various embodiments include or consist of a plastic material doped with electrically conductive material, for example doped with carbon black, carbon fibers and/or with metal particles. The electrically conductive structure 524 may have a resistivity of less than 10⁻⁴ Ωm, for example a resistivity from about 10⁻⁷ Ωm to about 10⁻⁴ Ωm.

In various embodiments, the electrically conductive structure 524 of the package arrangement 400, for example the electrically conductive molding compound, may be formed analogously to the molding described in connection with forming the encapsulation material 110 in FIG. 1C.

FIG. 5 shows a schematic diagram 500 of a method for forming a package arrangement in accordance with various embodiments.

The method may include: arranging at least one chip over a carrier (in 5002); at least partially encapsulating the at least one chip with encapsulation material, wherein the encapsulation material is formed such that at least a portion of the carrier is uncovered by the encapsulation material (in 5004); forming an electrically conductive structure over the encapsulation material and on the portion of the carrier uncovered by the encapsulation material (in 5006); removing the carrier (in 5008); and then forming a redistribution structure over the chip and the electrically conductive structure, wherein the redistribution structure electrically couples the electrically conductive structure and the chip (in 5010).

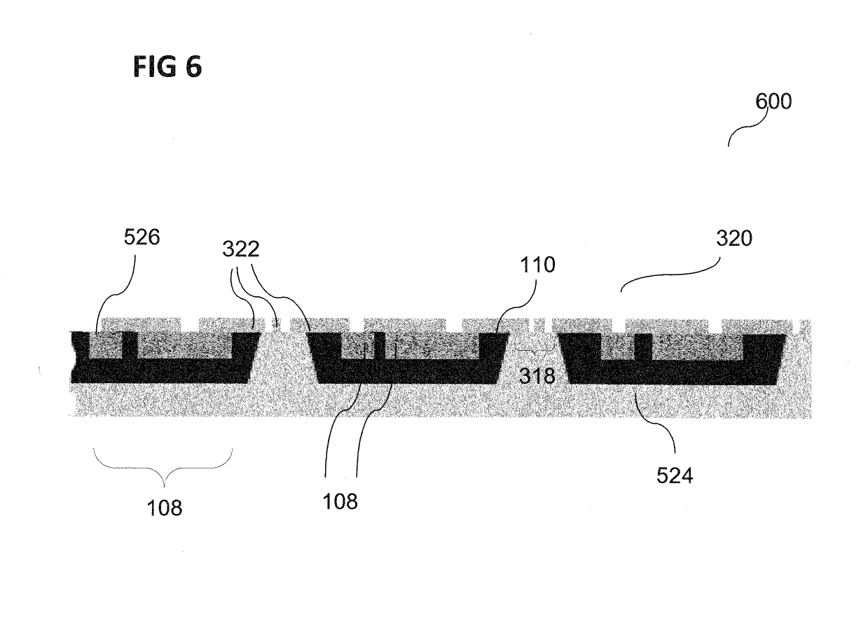

FIG. 6 shows a cross section of a package arrangement 600 in accordance with various embodiments. The package arrangement 600 may include at least one chip 108.

The chip 108 may be or include a transistor. For example, the chip 108 may be or include a metal oxide field effect transistor (MOSFET) such as a power MOSFET. The chip 108 may alternatively or additionally be or include a bipolar transistor such as an insulated gate bipolar transistor (IGBT). The chip 108 may include an integrated circuit such as a logic integrated circuit, a memory integrated circuit or a power integrated circuit. The integrated circuit may be an application specific integrated circuit (ASIC) or a field programmable gate array (FPGA). As an alternative, the integrated circuit may be any other programmable logic circuit such as e.g. a programmable processor, e.g. a programmable microprocessor or programmable nanoprocessor. The chip 108 may additionally or alternatively include a capacitor, an inductor, a resistor or any other electrical components.

The package arrangement 600 may further include encapsulation material 110 encapsulating the chip 108, wherein at least a first side of the chip 108 may be uncovered by the encapsulation material 110. In various embodiments, the chip 108 may be uncovered by the encapsulation material 110 only on the first side of the chip 108. In various other embodiments, the chip 108 may for example also be uncovered by the encapsulation material on edge surfaces between the first side of the chip 108 and a side opposite the first side of the chip 108. The encapsulation material 110 may include or consist of a dielectric material, for example a dielectric dispensable or printable dielectric material, or a dielectric laminate.

The package arrangement 600 may further include an electrically conductive structure 524 formed over the encapsulating material 110 (wherein “over” is to be understood as forming the electrically conductive structure 524 directly or indirectly on the encapsulating material, as described above, and not as indicating the relative locations/orientations of encapsulating material 110 and electrically conductive structure 524 in the drawing). the electrically conductive structure 524, however, may include or consist of a conductive molding compound, for example an electrically conductive molding compound. The electrically conductive structure 524 may in various embodiments include or consist of an electrically conductive molding compound, for example a plastic material doped with electrically conductive material, for example doped with carbon black, carbon fibers and/or with metal particles. The electrically conductive structure 524 may in various other embodiments consist of or include metal, for example copper or aluminum. The electrically conductive structure 524 may have a resistivity of less than 10⁻⁴ Ωm, for example a resistivity in the range from about 10⁻⁷ Ωm to about 10⁻⁴ Ωm.

The package arrangement 600 may further include a redistribution structure 322 formed over the first side 526 of the chip 108 and over the electrically conductive structure 524, wherein the redistribution structure 322 electrically couples the electrically conductive structure 524 and the chip 108, and wherein the redistribution structure 322 is arranged in a plane substantially parallel to the chip 108.

In various embodiments, the redistribution structure may electrically couple the electrically conductive structure 114 and the chip 108 by being electrically connected to at least one portion 318 of the electrically conductive structure 114 and the at least one chip 108. The at least one portion 318 of the electrically conductive structure 114 may be arranged in the same plane as the first side 526 of the chip 108. In various embodiments, the redistribution structure 322 may be discontinuous.

In various embodiments, the redistribution structure 322 may include one or more metallization layers or interconnects. The metallization layers or interconnects may include an electrically conductive material such as e.g. a metal such as e.g. copper or aluminum. The metallization layers or interconnects may be configured for current redistribution. In other words, the metallization layer or interconnects may serve as or be configured as one or more redistribution layers (RDLs). The redistribution structure 322 may further include one or more dielectric or insulating material/layers such as polymer (e.g. polyimide, epoxy, silicone, ormocere etc) or silicon oxide. The metallization layers (or interconnects) may be separated from one another by the dielectric (or insulating) layers. The redistribution structure 322 may include a laminate. The redistribution structure 322 may include a glass fibre core, for example.

In various embodiments, the redistribution structure 322 may have a thickness in a range from about 5 μm to about 1000 μm, e.g. from about 10 μm to about 200 μm.

In various embodiments, the multi-layer structure may include a thin-film multi-layer structure. The redistribution structure 322 may include one or more thin film metallization layers. The redistribution structure 322 may also include one or more thin film dielectric or insulating layers. The thin film metallization layers may be separated from one another by the dielectric (or insulating) layers. Each thin-film layer may have a thickness below about 50 μm, e.g. below about 15 μm e.g. from about 0.5 μm to about 10 μm.

In various embodiments, the redistribution structure 322 may be coupled to a reference potential. The chip 108 may provide the reference potential. The reference potential may be at ground. In various embodiments, the electrically conductive structure 114 may be configured as an electromagnetic shield such as a radio frequency shielding structure. The electrically conductive structure 114 may be electrically coupled to the chip 108 via the redistribution structure 322. The electrically conductive structure 114 may be also coupled to the reference potential.

The package arrangement 600 may further include further encapsulation material over the electrically conductive structure.

In various embodiments, a method for forming a package arrangement is provided. The method may include: arranging at least one chip over a carrier; at least partially encapsulating the at least one chip with encapsulation material, wherein the encapsulation material is formed such that at least a portion of the carrier is uncovered by the encapsulation material; forming an electrically conductive structure over the encapsulation material and on the portion of the carrier uncovered by the encapsulation material; removing the carrier; and then forming a redistribution structure over the chip and the electrically conductive structure, wherein the redistribution structure electrically couples the electrically conductive structure and the chip.

In various embodiments, the redistribution structure may be arranged in a plane substantially parallel to the chip. The method may further include arranging further encapsulation material over the electrically conductive structure. In various embodiments, the electrically conductive structure may comprise a conducting molding compound. In various embodiments, the electrically conductive structure may be configured as a radio frequency shielding structure. In various embodiments, the electrically conductive structure may be formed continuously. In various embodiments, at least partially encapsulating the at least one chip with encapsulation material may include molding the encapsulation material such that at least a portion of the carrier is uncovered by the encapsulation material. In various embodiments, forming an electrically conductive structure over the encapsulation material and on the portion of the carrier uncovered by the encapsulation material may include sputter depositing the electrically conductive structure.

In various embodiments, a package arrangement is provided. The package arrangement may include at least one chip; encapsulating material encapsulating the chip, wherein at least a first side of the chip is uncovered by the encapsulating material; an electrically conductive structure formed over the encapsulating material; and a redistribution structure formed over the first side of the chip and over the electrically conductive structure, wherein the redistribution structure electrically couples the electrically conductive structure and the chip, and wherein the redistribution structure is arranged in a plane substantially parallel to the chip.

In various embodiments, the package arrangement may further include further encapsulation material over the electrically conductive structure. In various embodiments, the electrically conductive structure may include a conducting molding compound.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for forming a package arrangement, the method comprising:
arranging at least one chip over a carrier;
at least partially encapsulating the at least one chip with encapsulation material, wherein the encapsulation material is formed such that at least a portion of the carrier is uncovered by the encapsulation material;
forming an electrically conductive structure over the encapsulation material and on the portion of the carrier uncovered by the encapsulation material;
removing the carrier; and
then forming a redistribution structure over the chip and the electrically conductive structure, wherein the redistribution structure electrically couples the electrically conductive structure and the chip.

2. The method of claim 1,
wherein the redistribution structure is arranged in a plane substantially parallel to the chip.

3. The method of claim 1, further comprising:
arranging further encapsulation material over the electrically conductive structure.

4. The method of claim 1,
wherein the electrically conductive structure comprises a conducting molding compound.

5. The method of claim 1,
wherein the electrically conductive structure is configured as a radio frequency shielding structure.

6. The method of claim 1,
wherein the electrically conductive structure is formed continuously.

7. The method of claim 1,
wherein at least partially encapsulating the at least one chip with encapsulation material comprises molding the encapsulation material such that at least a portion of the carrier is uncovered by the encapsulation material.

8. The method of claim 1,
wherein forming an electrically conductive structure over the encapsulation material and on the portion of the carrier uncovered by the encapsulation material comprises sputter depositing the electrically conductive structure.

9. A package arrangement, comprising
at least one chip;
encapsulating material encapsulating the chip, wherein at least a first side of the chip is uncovered by the encapsulating material;
an electrically conductive structure formed over the encapsulating material; and
a redistribution structure formed over the first side of the chip and over the electrically conductive structure,
wherein the redistribution structure electrically couples the electrically conductive structure and the chip, and
wherein the redistribution structure is arranged in a plane substantially parallel to the chip.

10. The package arrangement of claim 9, further comprising:
further encapsulation material over the electrically conductive structure.

11. The package arrangement of claim 9,
wherein the electrically conductive structure comprises a conducting molding compound.
